(19) United States
(12) Patent Application Publication
(10) Pub. No.: US 2011/0281416 A1
(43) Pub. Date: Nov. 17, 2011

(54) Manufacturing method of semiconductor device

(75) Inventors: Takayoshi Hashimoto, Osaka-shi (JP); Hisashi Yonemoto, Osaka-shi (JP)

(73) Assignee: Sharp Kabushiki Kaisha, Osaka (JP)

(21) Appl. No.: 13/067,146

(22) Filed: May 12, 2011

(30) Foreign Application Priority Data
May 14, 2010 (JP) 2010-112178

(51) Int. Cl. H01L 21/762

(52) U.S. Cl. 438/424; 257/E21.546

(57) ABSTRACT

The present invention provides a manufacturing method of a semiconductor device including: a step of forming a shallow trench on a semiconductor substrate; a step of forming an insulating layer in the shallow trench; and a step of forming a deep trench in the shallow trench, the deep trench penetrating through the insulating layer and being deeper than the shallow trench; wherein the step of forming the deep trench includes to form a first deep trench including an inner side face having a first taper angle with respect to the semiconductor substrate; and form a second deep trench including an inner side face having a second taper angle with respect to the semiconductor substrate, wherein the second taper angle is different from the first taper angle.

### CROSS-REFERENCE TO RELATED APPLICATION

This application is related to Japanese Patent Application No. 2010-112178 filed on May 14, 2010, whose priority is claimed and the disclosure of which is incorporated by reference in its entirety.

### BACKGROUND OF THE INVENTION

1. Field of the Invention

The present invention relates to a manufacturing method of a semiconductor device.

2. Description of the Background Art

A deep trench isolation is utilized as a means for realizing a high integration and high reliability of a semiconductor device. A deep trench structure is known as an element isolation, and it is used for isolating a well and a well.

For example, in a BiCMOS semiconductor device having a MOS transistor and a bipolar transistor mixed therein, the MOS transistor is isolated with a shallow trench, while the bipolar transistor is isolated with a deep trench, in order to increase an integration degree. A liquid crystal driver includes a control circuit composed of a low-voltage logic transistor, and a drive circuit composed of a high-voltage transistor, wherein a deep well is employed in order to attain a resistance to a high voltage. On the other hand, the deep trench structure is employed in order to prevent that a parasitic thyristor between wells becomes a latch-up state, when a trigger signal is inputted, to destroy the liquid crystal driver. In the liquid crystal driver, the deep trench is formed in the region where the shallow trench or LOCOS is formed.

It has been known that the deep trench described above is formed by steps as described below. Specifically, the deep trench is formed by a step of forming the deep trench by a reactive ion etching (RIE) on a semiconductor substrate, and filling the deep trench with a silicon oxide film and a polysilicon, and a step of forming a shallow trench with the reactive ion etching, and filling the shallow trench with the silicon oxide film (e.g., see Japanese Unexamined Patent Publication No. 2-54559).

It has also been known that the deep trench is formed by a step of forming a shallow trench on a semiconductor substrate, and filling the shallow trench with an insulating film, and a step of further forming a deep trench and filling the deep trench with another insulating film (e.g., see Japanese Unexamined Patent Publication No. 10-56059).

It has also been known that the deep trench is formed in such a manner that a shallow trench is formed, a deep trench is formed at the center of the bottom surface of the shallow trench, and the deep trench is filled with a silicon oxide film and a polysilicon (e.g., see WO2005/001939).

However, in the manufacturing method of the deep trench, the deep trench is formed under a uniform etching condition, so that a deep trench having a depth and width corresponding to a size of an opening for a resist mask formed by a photolithography technique can only be formed. Therefore, the size of the deep trench is limited by a resolution of the photolithography technique. Accordingly, a method of forming a deep trench in which the size of the deep trench is not dependent on the resolution of the photolithography technique has been desired.

### SUMMARY OF THE INVENTION

The present invention has been made in consideration of the problem described in the foregoing, and an object thereof is to provide a manufacturing method of a semiconductor device provided with a deep trench whose size is not dependent on the resolution of the photolithography technique.

The present invention provides a manufacturing method of a semiconductor device including: a step of forming a shallow trench on a semiconductor substrate; a step of forming an insulating layer in the shallow trench; and a step of forming a deep trench in the shallow trench, the deep trench penetrating through the insulating layer and being deeper than the shallow trench; wherein the step of forming the deep trench includes to form a first deep trench including an inner side face having a first taper angle with respect to the semiconductor substrate; and to form a second deep trench including an inner side face having a second taper angle with respect to the semiconductor substrate, wherein the second taper angle is different from the first taper angle.

According to the manufacturing method of a semiconductor device of the present invention, the step of forming, in the shallow trench, the deep trench, which penetrates through the insulating layer and which is deeper than the shallow trench includes the step of forming the first deep trench in which the side face of the deep trench has the first taper angle with respect to the semiconductor substrate; and the step of forming the second deep trench in which the side face of the deep trench has the second taper angle with respect to the semiconductor substrate, wherein the second taper angle is different from the first taper angle. Therefore, the trench having a smaller width of the bottom surface can be formed, compared to a method of forming the deep trench with a constant taper angle. Accordingly, the deep trench that is smaller than the conventional deep trench, which corresponds to the size of the opening of the resist mask formed by the photolithography technique, can be formed. Consequently, the present invention can provide the manufacturing method of a semiconductor device provided with the deep trench whose size is not dependent on the resolution of the photolithography technique.

### BRIEF DESCRIPTION OF THE DRAWINGS

FIG. 1 is a sectional view for describing steps of a manufacturing method of a semiconductor device according to an embodiment of the present invention;

FIG. 2 is a sectional view for describing steps of the manufacturing method of a semiconductor device according to the embodiment of the present invention;

FIG. 3 is a graph illustrating a relationship between a flow ratio of an etching gas and a taper angle of a trench in a step of forming a deep trench according to the embodiment of the present invention;

FIG. 4 is a sectional view for describing steps of a manufacturing method of a semiconductor device according to a background art;

FIG. 5 is a sectional view for describing steps of the manufacturing method of a semiconductor device according to the background art; and

FIG. 6 is a sectional view for describing an etching residue in the manufacturing method of a semiconductor device according to the background art.

### DESCRIPTION OF THE PREFERRED EMBODIMENTS

A manufacturing method of a semiconductor device according to the present invention includes: a step of forming a shallow trench on a semiconductor substrate; a step of forming an insulating layer in the shallow trench; and a step of forming, in the shallow trench, a deep trench, which penetrates through the insulating layer and which is deeper than the shallow trench; wherein the step of forming the deep trench includes a step of forming a first deep trench in which a side face of the deep trench has a first taper angle with respect to the semiconductor substrate; and a step of forming a second deep trench in which the side face of the deep trench has a second taper angle with respect to the semiconductor substrate, wherein the second taper angle is different from the first taper angle.

For example, the second taper angle may be greater than the first taper angle.

In the manufacturing method described above, a step of forming an insulating layer on the semiconductor substrate with a LOCOS process may be employed, instead of the step of forming the shallow trench on the semiconductor substrate and the step of forming the insulating layer in the shallow trench.

In the manufacturing method of the semiconductor device according to the present invention, the step of forming the shallow trench may be a step of forming the shallow trench having a depth within a range of 0.2 to 1.5 μm, and the step of forming the first deep trench may be a step of forming the first deep trench in which the first taper angle is within a range of 70° or more and less than 90°. Further, the step of forming the second deep trench may be a step of forming the second deep trench having a width within a range of 0.2 μm or more and 2 μm or less, and a depth within a range of 3 μm or more and 20 μm or less, wherein the second taper angle is within a range of 85° or more and 90° or less.

The manufacturing method of the semiconductor device according to the present invention further includes, in addition to the steps described above, a step of forming an oxide film on the surface of the semiconductor substrate and on the surface of the deep trench; a step of forming a polysilicon layer on the oxide film for filling the deep trench with the polysilicon layer and of arranging the polysilicon layer on the semiconductor substrate via the oxide film; and a step of forming a gate electrode by etching the polysilicon layer in order to leave a part of the polysilicon layer on the semiconductor substrate, wherein the semiconductor device is the one having a MOS structure.

There has conventionally been known a manufacturing method in which components of a semiconductor device are formed after a deep trench is formed. For example, there has been known a manufacturing method of a semiconductor device employing the deep trench, wherein a semiconductor device is formed by a step of forming a deep trench, and subsequent steps following a step of forming a gate oxide film of MOSLSI (see, for example, Japanese Unexamined Patent Publication No. 2-54559). There has also been known another manufacturing method of a semiconductor device employing a deep trench, wherein a semiconductor device is formed by a step of forming a deep trench, and a subsequent step of forming an emitter polysilicon film (see, for example, Japanese Unexamined Patent Publication No. 10-56059).

As described above, in the conventional manufacturing methods of a semiconductor device employing the deep trench, components of the semiconductor device (e.g., the gate oxide film) are formed after a shallow trench and the deep trench are formed. Therefore, the conventional manufacturing methods described above includes a step of forming the shallow trench and a step of forming the deep trench, which entails a problem of increased number of steps. Accordingly, the reduction in the number of steps has been desired in the manufacture of the semiconductor device employing the deep trench structure. The present invention is accomplished in view of the above-mentioned circumstances, and aims to provide a simple manufacturing method from which a number of steps for manufacturing a semiconductor device employing the deep trench is decreased.

Specifically, according to another aspect of the manufacturing method of a semiconductor device according to the present invention, the oxide film formed on the surface of the semiconductor substrate and on the surface of the deep trench constitutes a gate oxide film in the MOS structure and an insulating film of the deep trench, and the polysilicon layer formed on the semiconductor substrate and in the deep trench constitutes a gate electrode in the MOS structure and a filling material of the deep trench. Therefore, the number of steps is lower than that in the manufacturing method of a semiconductor device having the MOS structure in which the gate oxide film and the gate electrode are formed after the shallow trench and the deep trench are formed.

In another aspect of the manufacturing method of a semiconductor device according to the present invention, the step of forming the oxide film on the surface of the semiconductor substrate and the surface of the deep trench after the shallow trench and the deep trench are formed, the step of forming the polysilicon layer on the oxide film, and the step of etching the polysilicon layer in order to leave a part of the polysilicon layer on the semiconductor substrate also serve as a step of allowing the surface of the deep trench to be isolated and filling the inside thereof, and a step of forming the gate oxide film and the gate electrode.

As described above, another aspect of the present invention can provide a simpler manufacturing method in which a number of manufacturing steps is decreased.

When the manufacturing method of a semiconductor device according to another aspect of the present invention is a method of manufacturing a semiconductor device having a MOS structure, the step of forming the gate electrode may be a step of polishing or etching back the polysilicon layer so as to have a prescribed thickness, and then, etching the polysilicon layer so as to leave the part of the polysilicon layer.

When the manufacturing method of a semiconductor device according to another aspect of the present invention is a method of manufacturing a semiconductor device having a MOS structure, the step of polishing or etching back the polysilicon layer may be a step of polishing or etching back the polysilicon layer in order that the thickness of the polysilicon layer becomes 100 to 500 nm.

When the manufacturing method of a semiconductor device according to another aspect of the present invention is a method of manufacturing a semiconductor device having a MOS structure, the step of forming the oxide film may be a step of forming the oxide film having a thickness of 5 to 150 nm.

When the manufacturing method of a semiconductor device according to another aspect of the present invention is a method of manufacturing a semiconductor device having a MOS structure, the step of forming the oxide film may be a step of forming a silicon nitride-oxide film.

When the manufacturing method of a semiconductor device according to another aspect of the present invention is a method of manufacturing a semiconductor device having a MOS structure, the step of forming the polysilicon layer may be a step of forming a polysilicon layer having a thickness of 0.1 μm or more and 1 μm or less.

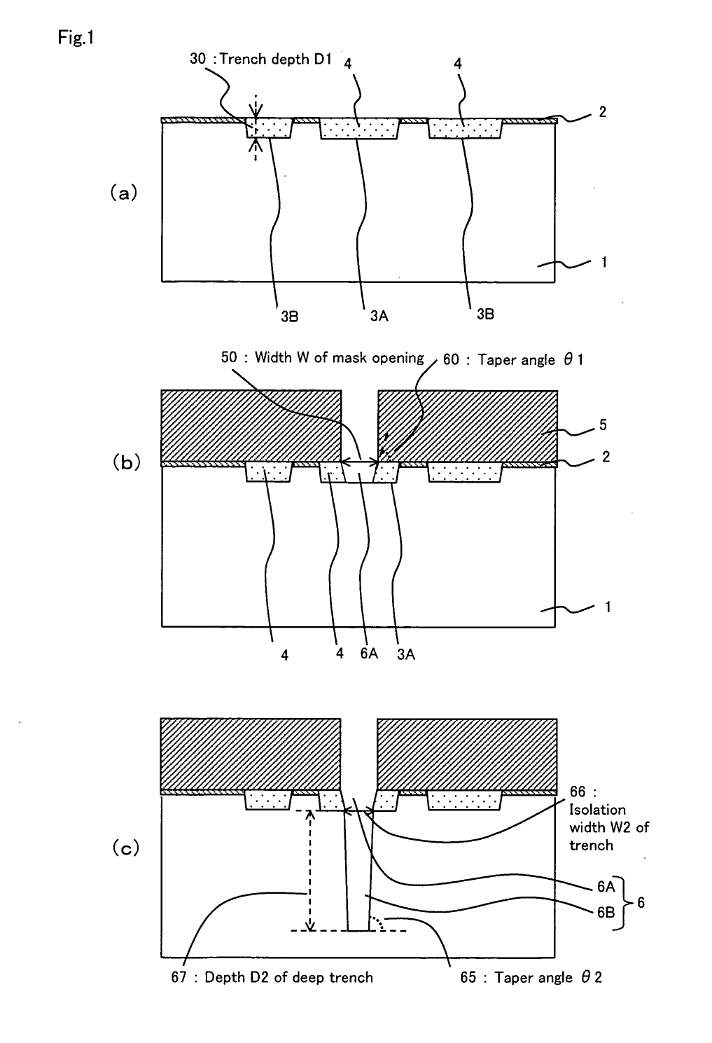

In the following, with reference to FIGS. 1 to 3, embodiments of the present invention will be described in detail. It is to be noted that the embodiments described below are only illustrative of the present invention, and it should not be construed that the present invention is limited to these embodiments.

### Embodiment

FIGS. 1 to 3 are sectional views for describing steps of a manufacturing method of a semiconductor device according to the embodiment of the present invention. The manufacturing method of a semiconductor device according to the present embodiment is a manufacturing method of a MOS transistor, wherein steps after a step of forming a gate electrode are the same as those in a conventional method. Therefore, steps before the gate electrode of the MOS transistor is formed will be described below.

As illustrated in FIG. 1(a), shallow trenches 3A and 3B are firstly formed on a silicon substrate 1, and then, an SiO₂ layer 4 serving as an insulating film is formed in the shallow trenches 3A and 3B. The shallow trenches 3A and 3B are formed with a method similar to a known STI method. Specifically, an SiO₂ layer 2 and Si₃N₄ layer (not illustrated) are formed on the semiconductor substrate, and an opening is formed on the SiO₂ layer 2 and the Si₃N₄ layer with a known photolithography technique. Then, the silicon substrate 1 is subject to a trench etching (e.g., RIE) by using the SiO₂ layer 2 and the Si₃N₄ layer, having the opening formed thereon, as a mask, so as to form grooves of the shallow trenches 3A and 3B. A depth 30 (a trench depth D1 illustrated in FIG. 1(a)) of each of the grooves of the shallow trenches 3A and 3B is preferably 0.2 to 1.5 μm. Subsequently, the inner wall of each of the grooves of the formed shallow trenches 3A and 3B is oxidized to form an oxide film (the formation of the SiO₂ layer). Next, the SiO₂ layer 4, serving as an insulating film, is deposited on the silicon substrate 1 with a CVD so as to fill the shallow trenches 3A and 3B with the SiO₂ layer 4. The thickness of the SiO₂ layer 4 is preferably 0.2 to 1.5 μm, like the shallow trenches 3A and 3B. Thereafter, the surface of the silicon substrate 1 is polished to planarized the surface, whereby the SiO₂ layer and the Si₃N₄ layer deposited at the outside of the shallow trenches 3A and 3B are removed.

In the present embodiment, the shallow trench 3A corresponds to an element isolation between circuits, while the shallow trench 3B corresponds to an element isolation between elements.

Next, deep trenches 6A and 6B, which penetrate through the SiO₂ layer 4 and which are deeper than the shallow trenches 3A and 3B, are formed in the shallow trench 3A.

Specifically a photoresist layer for the deep trench is firstly formed on the silicon substrate 1, and an opening is formed on the photoresist layer with the known photolithography technique. The opening is formed on the region of the shallow trench 3A.

Then, as illustrated in FIG. 1(b), the trench etching is performed with the photoresist layer 5 having the opening formed thereon being used as a mask, whereby the first deep trench 6A is formed on the SiO₂ layer 4 deposited in the shallow trench 3A. The trench etching is performed in such a manner that a taper angle 60 (θ1 illustrated in FIG. 1(b)) with respect to the surface of the SiO₂ layer 4 falls within a range of 70° or more and less than 90°.

In the present embodiment, the taper angle 60 illustrated in FIG. 1(b) is the taper angle on the side face (etched face) of the first deep trench 6A with respect to the surface of the SiO₂ layer 4. When the surface of the SiO₂ layer 4 is substantially parallel to the surface of the silicon substrate 1, it may be the taper angle of the side face of the first deep trench 6A with respect to the silicon substrate 1. In the present embodiment, the surface of the SiO₂ layer 4 and the surface of the silicon substrate 1 are substantially parallel to each other.

A width 50 (a width W1 of the mask opening portion) of the opening on the photoresist layer for the deep trench is set to be, for example, 0.2 μm or more and 2.0 μm or less, and a deep trench formed with an opening having the same size is formed on the SiO₂ layer 4 in the region where the shallow trench 3A is formed.

When the etching is performed up to the interface between the SiO₂ layer 4 in the shallow trench 3A and the silicon substrate 1 under the same etching condition, the shallow trench having the stable taper angle 60 can be formed. Therefore, the depth of the first deep trench may be set to be shallower than or equal to the depth of the shallow trench 3A. The depth of the first deep trench is preferably equal to the depth of the shallow trench 3A. In the case of the shallow trench 3A described above, the depth of the first deep trench 6A is preferably 0.2 to 1.5 μm.

For example, when the width 50 of the opening (the width W1 of the mask opening portion) of the photoresist layer is 1 μm, and the depth 30 (D1 illustrated in FIG. 1(a)) of the groove of the shallow trench 3A is 0.5 μm, the trench etching is performed in order that the taper angle 60 (θ1 illustrated in Fig. (b)) becomes 80°. In this case, a width 66 of the first deep trench 6A (an isolation width W2 of the trench) on the bottom surface of the groove of the shallow trench 3A becomes 0.82 μm.

The trench etching used for forming the first deep trench 6A is an anisotropic dry etching (e.g., RIE, magnetron-enhanced RIE).

When the anisotropic dry etching is the magnetron-enhanced RIE, it is preferable to use gases, such as CF₄/CHF₃/Ar, CF₄/CHF₃/Ar/O₂, C₄Fs/CHF₃/Ar/O₂, C₄Fs/Ar/O₂, or C₅F₈/Ar/O₂. One example of the etching condition in the magnetron-enhanced RIE is as described below.

Pressure: 75˜200 mTorr

RF power: 300˜600 W

Gaseous species/flow rate: CF₄/CHF₃/Ar=10˜100/10˜100/100˜200 sccm

Magnetic field: 0˜40 G

Through the etching under the condition described above, the first deep trench 6A can be formed to have the taper angle within a range of 70° or more and less than 90°.

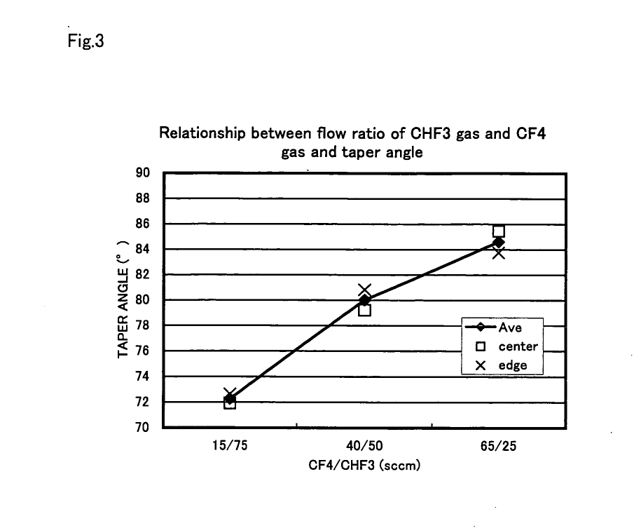

FIG. 3 illustrates a relationship between a gas flow ratio and the taper angle when the first deep trench 6A is formed on the silicon oxide film with the use of the above-mentioned etching gases. FIG. 3 is a graph illustrating a change of the taper angle on the side face of the silicon oxide film with respect to the surface of the silicon oxide film when the gas flow ratio of CF₄ gas and CHF₃ gas are varied in the anisotropic dry etching. The subject to be etched is the SiO₂ layer 4 that fills the shallow trench 3A. An axis of abscissa represents the gas flow ratio of CF₄ gas and CHF₃ gas, while an axis of ordinate represents the formed taper angle of the trench.

With reference to FIG. 3, it can be understood that the taper angle can be adjusted within the range of 72° to 85° by varying the gas flow ratio of CF₄ gas and CHF₃ gas. As described above, the first deep trench 6A can be formed with the taper angle of 70° or more and less than 90° by varying the gas flow ratio of the etching gas, for example.

As illustrated in FIG. 1(c), the second deep trench 6B is formed below the first deep trench 6A. Specifically, the SiO₂ layer 4 is subject to the trench etching with the photoresist layer 5, having the opening formed thereon, being used as a mask, so as to form the first deep trench 6A, and then, the trench etching is performed with a taper angle 65 greater than the taper angle of the first deep trench 6A. In this case, the etching is performed in such a manner that the taper angle 65 (θ2 illustrated in FIG. 1(c)) on the side face of the second deep trench 6B with respect to the surface of the substrate falls within the range of 85° or more and 90° or less. With this process, the second deep trench 6B is formed.

The taper angle 65 illustrated in FIG. 1(c) is the taper angle on the side face (etched face) of the second deep trench 6B with respect to the surface of the silicon substrate 1. In the present embodiment, the surface of the SiO₂ layer 4 and the surface of the silicon substrate 1 are substantially parallel to each other. Therefore, the taper angle 65 is equal to the angle of the side face of the second deep trench 6B with respect to the surface of the SiO₂ layer 4.

For example, when the width of the bottom surface of the first deep trench 6A is 0.2 μm or more and 2 μm or less, the etching is performed in such a manner that the taper angle of the second deep trench 6B falls within the range of 85° or more and 90° or less.

The second deep trench 6B having a depth 67 (D2 illustrated in FIG. 1(c)) of 3 μm or more and 20 μm or less is formed.

The trench etching used for forming the second deep trench 6B is the anisotropic etching (e.g., REI, ICP (Inductive Coupling Plasma) RIE), like the case of the first deep trench 6A. When the anisotropic dry etching used for forming the second deep trench 6B is the ICP RIE, it is preferable to use gases such as SF₆/HBr/O₂, SF₆/CHF₃/O₂, Cl₂/O₂, or HBr/Cl₂/O₂. One example of the etching condition in the ICP RIE is as described below.

Pressure: 5˜40 mTorr

RF source power: 500˜1200 W

RF bias power: 100˜250 W

Gaseous species/flow rate: HBr/O₂/SF₆=10˜100/10˜100/10˜100 sccm

Through the etching under the condition described above, the second deep trench 6B can be formed to have the taper angle 65 within a range of 85° or more and less than 90°.

The taper angle 65 of the second deep trench 6B may be different from the taper angle 60 of the first deep trench 6A, but the taper angle 65 of the second deep trench 6B may preferably be greater than the taper angle 60 of the first deep trench 6A. For example, the taper angle 60 of the first deep trench 6A may be 80°, and the taper angle 65 of the second deep trench 6B may be 88°.

The taper angle 65 of the second deep trench 6B may be formed to be greater than the taper angle 60 on the side face of the first deep trench 6A by an amount of 5° or more and less than 20°.

Next, the photoresist layer 5 having the opening formed thereon is removed after the second deep trench 6B is formed. Thus, the step of forming the deep trench 6 including the first and second deep trenches 6A and 6B is completed.

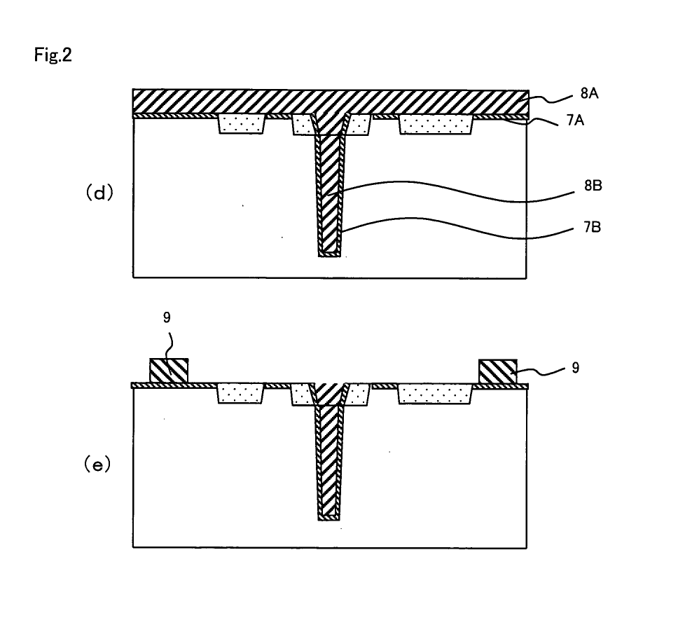

Then, as illustrated in FIG. 2(d), gate oxide films 7A and 7B are formed on the surface of the silicon substrate 1 and the surface of the deep trench 6, and then, polysilicon layers 8A and 8B are formed on the gate oxide films 7A and 7B.

The gate oxide film is formed by oxidizing the surface of the silicon substrate 1 and the surface of the deep trench 6. For example, the gate oxide film 7 is formed by a known thermal oxidation. In the thermal oxidation, a temperature is 800 to 850° C., and an oxidant is dry O₂, for example. The thickness of the gate oxide film 7 is preferably 5 to 150 nm. Therefore, the time for executing the oxidation process is determined so as to attain the thickness described above.

Nitrogen may be introduced with the oxidation into the oxide film with the use of HN₄, NO, or N₂O. In this case, the gate oxide film 7 is made of a silicon nitride-oxide film.

The gate oxide film 7 is preferably formed with the thermal oxidation, but a method such as an anodic oxidation, a plasma oxidation, a CVD method, a sputtering method, or vapor-deposition method may be used, instead of the thermal oxidation.

The gate oxide film 7A formed on the surface of the silicon substrate 1 corresponds to the gate oxide film of the MOS transistor, while the gate oxide film 7B formed on the surface of the deep trench 6 corresponds to the insulating film of the deep trench.

The polysilicon layer 8 is formed by a known CVD method. In this case, the thickness of the polysilicon layer is preferably set to be 0.1 μm or more and 1 μm or less in order to fill the deep trench 6. Since the polysilicon is deposited on the top surface of the silicon substrate 1 (on the surface where the gate oxide film 7, the SiO₂ layer 4 filling the shallow trenches 3A and 3B, and the deep trench 6 are formed), the inside of the deep trench 6 is filled with the polysilicon layer 8, and the polysilicon layer 8 is formed on the silicon substrate 1 through the gate oxide film 7.

The polysilicon layer 8 is preferably formed with the CVD method. However, instead of the CVD method, the sputtering method or vapor-deposition method may be used. With the method described above, the non-doped polysilicon layer 8 is formed.

The polysilicon layer 8A formed on the gate oxide film 7A on the surface of the silicon substrate 1 corresponds to the gate electrode of the MOS transistor by a later-described etching process, while the polysilicon layer 8B formed in the deep trench 6 corresponds to the filling material and insulating material of the deep trench.

Next, as illustrated in FIG. 2(e), the polysilicon layer 8 is etched in such a manner that a part of the polysilicon layer 8 is left on the silicon substrate 1, whereby a gate electrode 9 is formed.

A polysilicon CMP process or polysilicon etch-back process is performed in order that the polysilicon layer 8A on the silicon substrate 1 has a desired thickness. For example, the polysilicon CMP process is executed by a known chemical mechanical polishing. The polysilicon etch-back process may be performed by etching the polysilicon layer with the use of the etching gas having Cl₂ or CF₄ as a major component. With the processes described above, the thickness of the polysilicon layer is preferably set to be 100 to 500 nm. (The polysilicon layer 8A is formed with the polysilicon CMP process, preferably polysilicon etch-back process.)

Next, the polysilicon layer 8A is etched in order that the part of the polysilicon layer 8A is left, whereby the gate electrode 9 is formed. Specifically, a photoresist layer for the gate electrode is formed on the polysilicon layer 8A having the desired thickness, and then, an opening is formed on the photoresist layer with a known photolithography technique. The etching is performed with this photoresist layer being used as a mask so as to form the gate electrode 9.

Thus, the gate electrode 9 is formed on the silicon substrate 1 having the deep trench 6 formed thereon. Thereafter, impurities are introduced into the gate electrode 9 with a known manufacturing method of a MOS transistor, and source/drain regions and extracting electrode are formed, whereby the MOS transistor is completed.

### (Modification of Shallow Trench)

In the present embodiment, the shallow trenches 3A and 3B are formed, and then, the SiO₂ layer 4 serving as the insulating film is formed in the shallow trenches 3A and 3B. However, instead of forming the shallow trenches 3A and 3B and the SiO₂ layer 4, an SiO₂ layer serving as an element isolation layer may be formed on the silicon substrate 1 with the LOCOS process.

Like the embodiment for the shallow trenches, the thickness of the element isolation layer (SiO₂ layer) is preferably 0.2 to 1.5 μm. The taper angle of the first deep trench 6A is preferably within the range of 70° or more and less than 90°, like the embodiment for the shallow trenches.

In this embodiment, upon the formation of the deep trench 6, the etching is performed in such a manner that the taper angle of the side face of the first deep trench 6A with respect to the silicon substrate 1 falls within the range of 70° or more and less than 90°, and then, the etching is performed in such a manner that the taper angle of the side face of the second deep trench 6B with respect to the silicon substrate 1 falls within the range of 85° or more and 90° or less. Therefore, the trench having the smaller width of the bottom face thereof can be formed, compared to the process of forming the deep trench by performing the etching with a predetermined taper angle.

The gate oxide film 7A and the insulating film 7B of the deep trench are formed in the same process by oxidizing the surface of the silicon substrate 1 and the surface of the deep trench 6, and the gate electrode 8A and the filling material 8B of the deep trench are made by depositing the polysilicon layer onto the top surface of the silicon substrate 1. Therefore, the number of steps is reduced more than in the conventional manufacturing method of a semiconductor device in which the gate oxide film and the gate electrode are formed after the formation of the shallow trench and the deep trench. Accordingly, the manufacturing method of a semiconductor device according to the present embodiment can reduce the number of steps, compared to the conventional manufacturing method of a semiconductor device, whereby a MOS transistor can more simply be manufactured.

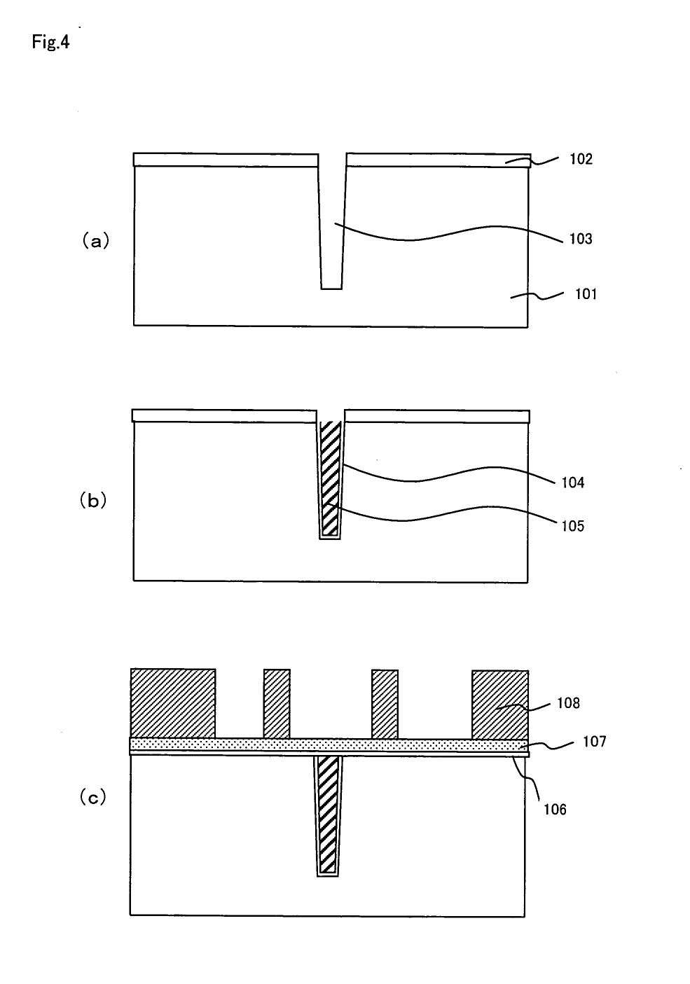

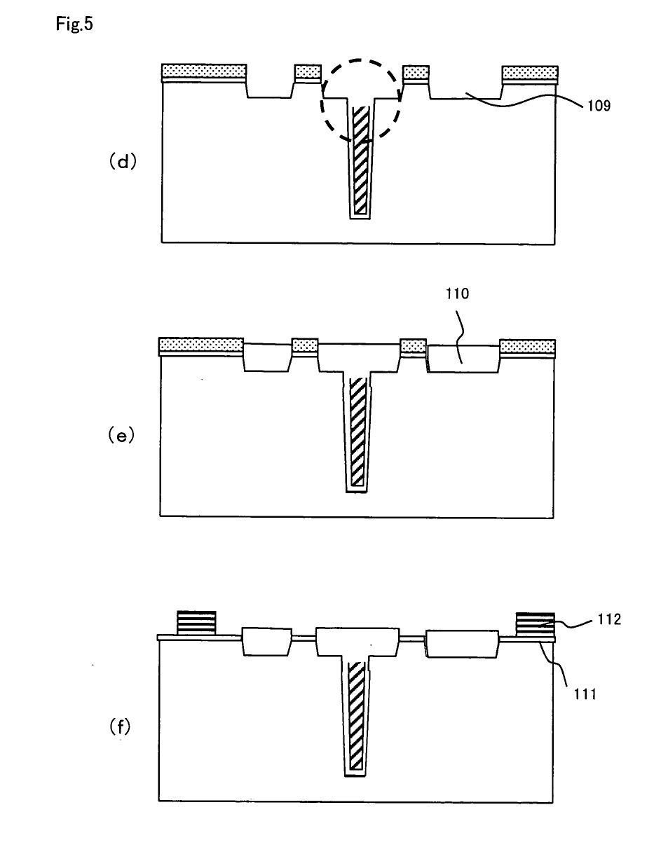

An etching residue produced in the opening of the deep trench by the manufacturing method of a semiconductor device illustrated in FIGS. 4 and 5 is not produced according to the manufacturing method of the present embodiment. The manufacturing method of a semiconductor device will be described in order to explain the etching residue.

FIGS. 4 and 5 are sectional views for describing processes of the manufacturing method of a semiconductor device according to a background art of the present invention. In this manufacturing method, an opening is formed with a known photolithography technique on a silicon oxide film 102 serving as a mask, and then, a deep trench 103 is formed with the use of the mask, as illustrated in FIG. 4(a). Next, as illustrated in FIG. 4(b), an oxide film 104 is formed on the inner surface of the deep trench 103, and then, the deep trench is filled with a polysilicon film 105. Thereafter, a polysilicon etch-back process is executed.

Subsequently, as illustrated in FIG. 4(c), a silicon oxide film 106 and a silicon nitride film 107 are formed, and then, an opening is formed with the known photolithography technique on the silicon nitride film 106 and the silicon oxide film 107. Thereafter, a photoresist 108 used in the photolithography technique is peeled. Next, as illustrated in FIG. 5(d), the trench etching is performed with the silicon nitride film 107 being used as a mask so as to form a shallow trench 109 on the region around the deep trench 103 on the silicon substrate 1. Thereafter, as illustrated in FIG. 5(e), a silicon oxide film 110 is filled in the shallow trench 109, and then, a planarizing process is performed with the CMP. Thereafter, the silicon nitride film 107 and the silicon oxide film 106 are removed. After various injections such as an injection into a well are performed, a gate oxide (the formation of a gate oxide film 111) and a polysilicon film for a gate electrode are deposited, and then, a gate electrode 112 is formed by using a resist mask for the process of the gate electrode (FIG. 5(f)).

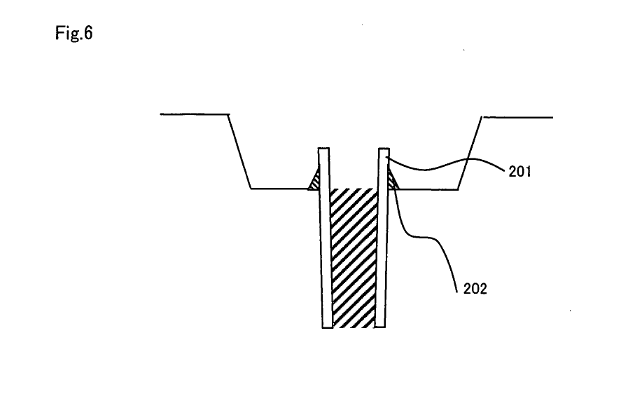

In the manufacturing method of a semiconductor device illustrated in FIGS. 4 and 5, an etching residue is generated in the step of forming the shallow trench 109 by the trench etching illustrated in FIG. 5(d). FIG. 6 is a sectional view for describing the etching residue in the manufacturing method according to the background art, wherein the bottom surface (the encircled portion in FIG. 5(d)) of the shallow trench 109 in FIG. 5(d) is enlarged.

As illustrated in FIG. 6, the etching residue is generated on the opening of the deep trench 103 at the bottom surface of the shallow trench 109. Specifically, the oxide film 104 on the inner surface of the deep trench 103 is not completely etched, so that the oxide film 104 remains in the form of a projection 201. The etching residue is produced between the projecting oxide film 201 and the bottom surface of the shallow trench 109 in such a manner that the silicon substrate 1 holds the projecting oxide film 201. The generation of the etching residue described above might entail a deterioration in a performance due to concentration of electric charges.

However, in the manufacturing method of a semiconductor device according to the embodiment of the present invention, the deep trench is formed after the shallow trench is formed. Therefore, the etching residue is not produced at the opening of the deep trench. Accordingly, the present embodiment can provide the manufacturing method of a semiconductor device whose electrical characteristic is difficult to be deteriorated.

The present invention is not limited to the embodiments described above, but various modifications are possible within the scope of the claims. Specifically, embodiments obtained by combining technical means, which are appropriately changed within the scope of the claims, are also included in the technical scope of the present invention.

What is claimed is:

1. A manufacturing method of a semiconductor device including:
a step of forming a shallow trench on a semiconductor substrate;
a step of forming an insulating layer in the shallow trench; and
a step of forming a deep trench in the shallow trench, the deep trench penetrating through the insulating layer and being deeper than the shallow trench;
wherein the step of forming the deep trench includes to form a first deep trench including an inner side face having a first taper angle with respect to the semiconductor substrate; and to form a second deep trench including an inner side face having a second taper angle with respect to the semiconductor substrate, wherein the second taper angle is different from the first taper angle.

2. The manufacturing method of a semiconductor device according to claim 1, further including:
a step of forming an oxide film on the surface of the semiconductor substrate and on the inner surface of the deep trench;
a step of forming a polysilicon layer on the oxide film for filling the deep trench with the polysilicon layer and of arranging the polysilicon layer on the semiconductor substrate via the oxide film; and
a step of forming a gate electrode by etching the polysilicon layer in order to leave a part of the polysilicon layer on the semiconductor substrate, wherein the semiconductor device is the one having a MOS structure.

3. The manufacturing method of a semiconductor device according to claim 2, wherein
the step of forming the gate electrode includes a step of polishing or etching back the polysilicon layer so as to have a prescribed thickness, and then, etching the polysilicon layer so as to leave the part of the polysilicon layer.

4. The manufacturing method of a semiconductor device according to claim 2, wherein
the step of forming the oxide film includes to form the oxide film having a thickness of 5 to 150 nm.

5. The manufacturing method of a semiconductor device according to claim 2, wherein
the step of forming the oxide film includes to form a silicon nitride-oxide film.

6. The manufacturing method of a semiconductor device according to claim 2, wherein
the step of forming the polysilicon layer includes to form a polysilicon layer having a thickness of 0.1 μm or more and 1 μm or less.

7. The manufacturing method of a semiconductor device according to claim 3, wherein
the step of polishing or etching back the polysilicon layer includes to polish or etch back the polysilicon layer in order that the thickness of the polysilicon layer becomes 100 to 500 nm.

8. The manufacturing method of a semiconductor device according to claim 1, wherein
the step of forming the shallow trench includes to form the shallow trench having a depth within a range of 0.2 to 1.5 μm, and
the step of forming the first deep trench includes to form the first deep trench in which the first taper angle is within a range of 70° or more and less than 90°.

9. The manufacturing method of a semiconductor device according to claim 1, wherein
the step of forming the second deep trench includes to form the second deep trench having a width within a range of 0.2 μm or more and 2 μm or less, and a depth within the range of 3 μm or more and 20 μm or less, wherein the second taper angle is within the range of 85° or more and 90° or less.
